(19) United States
(12) Patent Application Publication
(10) Pub. No.: US 2026/0290748 A1
(43) Pub. Date: Sep. 24, 2026

(54) ION IMPLANTER AND ION IMPLANTATION METHOD

(71) Applicant: Sumitomo Heavy Industries Material Solutions Co., Ltd., Tokyo (JP)

(72) Inventors: Taisei FUTAKUCHI, Ehime (JP); Kazuhisa ISHIBASHI, Ehime (JP); Tetsuo TAKAHASHI, Ehime (JP)

(21) Appl. No.: 19/670,079

(22) Filed: May 7, 2026

Related U.S. Application Data
(63) Continuation of application No. PCT/JP2024/036635, filed on Oct. 15, 2024.

(30) Foreign Application Priority Data
Nov. 14, 2023 (JP) 2023-193828

(51) Int. Cl. H01J 37/304; H01J 37/30; H01J 37/317

(52) U.S. Cl. CPC H01J 37/304; H01J 37/3007; H01J 37/3171; H01J 2237/10; H01J 2237/24521; H01J 2237/24528; H01J 2237/30416; H01J 2237/30477

(57) ABSTRACT

An ion implanter includes a beam generation device configured to operate in accordance with a plurality of operation parameters to generate an ion beam, an implantation processing chamber in which a workpiece is irradiated with the ion beam, a measurement device that measures a beam characteristic of the ion beam, a memory that stores a model for estimating the beam characteristic from a set of setting values of the plurality of operation parameters, and a predetermined program, and a processor that executes the predetermined program. In accordance with the predetermined program, the processor updates the model by using a plurality of measurement values of the beam characteristic and a plurality of estimated values of the estimated beam characteristic, and determines a target set of the setting values of the plurality of operation parameters for generating the ion beam which satisfies a desired beam characteristic by using the updated model.

### CROSS-REFERENCE TO RELATED APPLICATIONS

This is a bypass continuation of International PCT Application No. PCT/JP2024/036635, filed on Oct. 15, 2024, which claims priority to Japanese Patent Application No. 2023-193828, filed on Nov. 14, 2023, which are incorporated by reference herein in their entirety.

### BACKGROUND

### Technical Field

Certain embodiments of the present invention relate to an ion implanter and an ion implantation method.

### Description of Related Art

In a semiconductor manufacturing process, a process of implanting ions into a semiconductor wafer (also referred to as an ion implantation process) is standardly performed to change conductivity of a semiconductor, to change a crystal structure of the semiconductor, or the like. A device used for the ion implantation process is called an ion implanter. The ion implanter is configured to realize desired beam characteristics by measuring beam characteristics such as a beam current and a beam angle of an ion beam to be used in irradiating a wafer and adjusting an operation parameter, based on a measurement value.

### SUMMARY

According to an embodiment of the present invention, there is provided an ion implanter including a beam generation device configured to operate in accordance with a plurality of operation parameters to generate an ion beam, an implantation processing chamber in which a workpiece is irradiated with the ion beam, a measurement device that measures a beam characteristic of the ion beam, a memory that stores a model for estimating the beam characteristic from a set of setting values of the plurality of operation parameters, and a predetermined program, and a processor that executes the predetermined program. In accordance with the predetermined program, the processor updates the model by using a plurality of measurement values of the beam characteristic measured when each of a plurality of sets of the setting values of the plurality of operation parameters is set as the plurality of operation parameters, and a plurality of estimated values of the beam characteristic estimated by using the model from each of the plurality of sets, and the processor determines a target set of the setting values of the plurality of operation parameters for generating an ion beam which satisfies a desired beam characteristic by using the updated model.

According to another embodiment of the present invention, there is provided an ion implantation method. This method includes measuring a plurality of measurement values of a beam characteristic of an ion beam generated by a beam generation device when each of a plurality of sets of setting values of a plurality of operation parameters is set, as a plurality of operation parameters of the beam generation device configured to generate the ion beam by operating in accordance with the plurality of operation parameters, estimating a plurality of estimated values of the beam characteristic corresponding to each of the plurality of sets by using a model for estimating the beam characteristic from the set of setting values of the plurality of operation parameters, updating the model by using the plurality of measurement values and the plurality of estimated values of the beam characteristic, determining a target set of the setting values of the plurality of operation parameters for generating the ion beam which satisfies a desired beam characteristic by using the updated model, and irradiating a workpiece with the ion beam generated by the beam generation device when the target set is set as the plurality of operation parameters.

### BRIEF DESCRIPTION OF THE DRAWINGS

FIG. 1 illustrates a top view of a schematic configuration of an ion implanter, according to an embodiment.

FIGS. 2A and 2B are front views illustrating a schematic configuration of an electrostatic quadrupole lens device.

FIG. 3 is a diagram schematically illustrating a configuration of a central control device.

FIG. 4 is a block diagram schematically illustrating a functional configuration of the central control device.

FIG. 5 is a flowchart illustrating an example of a method for adjusting an operation parameter.

FIG. 6 is a flowchart illustrating an example of a method for adjusting a beam characteristic.

FIG. 7 is a diagram schematically illustrating an example of a model indicating a correlation between a setting value of a plurality of operation parameters and a beam characteristic.

FIG. 8 is a diagram schematically illustrating a plurality of sets of setting values of the plurality of operation parameters set on the model.

FIG. 9 is a diagram schematically illustrating an example of a method for evaluating validity of the model.

FIG. 10 is a diagram schematically illustrating an example of the model indicating a correlation between the setting value of the plurality of operation parameters and the beam characteristic.

FIG. 11 is a diagram schematically illustrating a method for determining a target set of the setting values of the plurality of operation parameters by using a plurality of the models.

FIG. 12 is a flowchart illustrating an example of an ion implantation method according to an embodiment.

### DETAILED DESCRIPTION

In recent years, accuracy in the beam characteristics is more strictly required, and this strictly required accuracy may need a time for performing adjustment for realizing desired beam characteristics. In addition, even when the operation parameter having an actual result in the past is used, in some cases, the beam characteristics obtained in the past cannot be realized without any change. In this case, time-consuming measurement and adjustment have to be repeated. When a time required for performing this adjustment is lengthened, productivity of the ion implanter is degraded.

It is desirable to provide a technique for quickly and accurately adjusting an operation parameter.

Any combinations of components described above or those which the components or expressions of the present invention are replaced with each other between methods, devices, systems, or the like are also effective as embodiments of the present invention.

Hereinafter, embodiments for implementing the present invention will be described in detail with reference to drawings. In describing the drawings, the same reference numerals will be assigned to the same elements, and repeated description will be appropriately omitted. In addition, configurations described below are merely examples, and do not limit the scope of the present invention in any way.

A summary will be described before the embodiments are described in detail. According to the present embodiment, there is provided an ion implanter including a beam generation device configured to operate in accordance with a plurality of operation parameters to generate an ion beam, an implantation processing chamber in which a workpiece is irradiated with the ion beam, a measurement device that measures a beam characteristic of the ion beam, a memory that stores a predetermined program and a model for estimating the beam characteristic from a set of setting values of the plurality of operation parameters, and a processor that executes the predetermined program. In accordance with a predetermined program, the processor operates and estimates the beam characteristic by using the model from a set of the setting values of the plurality of operation parameters. Since the beam characteristic can be estimated by using the model, in some cases, measurement of the beam characteristic can be omitted. Therefore, a desired beam characteristic can be obtained without repeating time-consuming measurement and adjustment.

However, due to an individual difference or a time-dependent change in the ion implanter, in some cases, an actual state of the ion implanter and a state estimated by the model may deviate from each other, and estimated accuracy of the beam characteristic by the model may be degraded. In this case, the beam characteristic is less likely to be highly accurately estimated by the model generated, based on the actual result data or the like in the past. Therefore, in the present embodiment, when the estimated accuracy of the model is low, the model is updated by using a relationship between the measurement value and the estimated value of the beam characteristic, and a state estimated by the updated model is caused to coincide with or is closer to the current state of the ion implanter. Since the model is frequently updated due to the individual difference or the time-dependent change in the ion implanter, a state where the estimated accuracy of the model is high, and the desired beam characteristic can be obtained without repeating the time-consuming measurement and adjustment.

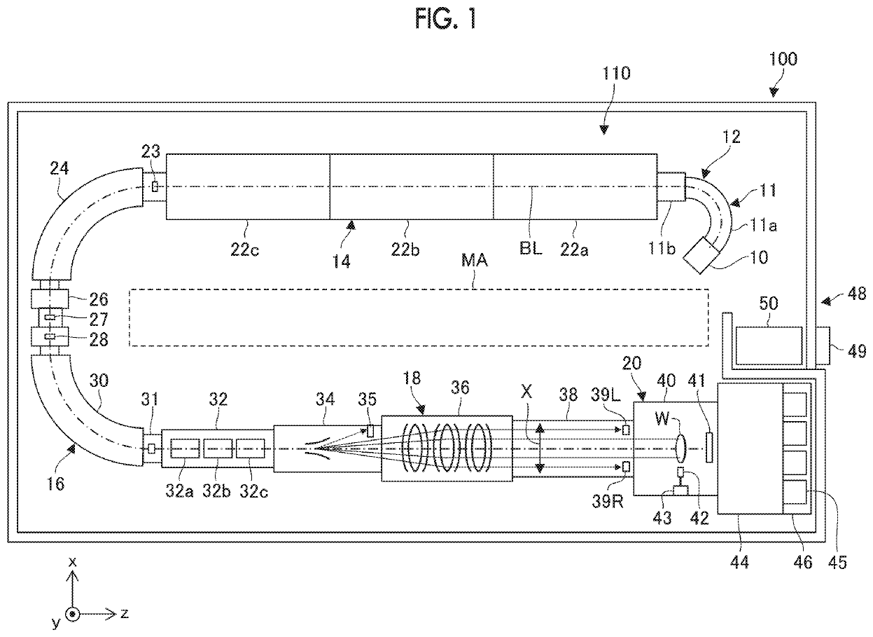

FIG. 1 is a top view schematically illustrating an ion implanter 100 according to an embodiment. The ion implanter 100 includes a beam generation device 110. The beam generation device 110 can include an ion generation device 12, a beam accelerator 14, a beam deflecting device 16, and a beam transport device 18. The ion implanter 100 further includes a substrate transport process device 20. The beam generation device 110 can be used as a generic term representing at least one of the ion generation device 12, the beam accelerator 14, the beam deflecting device 16, and the beam transport device 18.

The ion generation device 12 includes an ion source 10 and a mass analyzer 11. In the ion generation device 12, an ion beam is extracted from the ion source 10, and the extracted ion beam is subjected to mass analysis by the mass analyzer 11. The mass analyzer 11 includes a mass analyzing magnet 11a and a mass resolving aperture 11b. The mass resolving aperture 11b is disposed on a downstream side of the mass analyzing magnet 11a. As a result of the mass analysis performed by the mass analyzer 11, only an ion species required for implantation is selected, and the ion beam of the selected ion species is guided to a subsequent beam accelerator 14.

The beam accelerator 14 includes a plurality of linear accelerators 22a, 22b, and 22c for accelerating the ion beam and a beam measurement unit 23, and forms a linearly extending portion in a beamline BL. Each of the plurality of linear accelerators 22a to 22c includes radio frequency accelerators in one or more stages, and causes a radio frequency (RF) electric field to act on and accelerate the ion beam. The beam measurement unit 23 is provided on the most downstream side of the beam accelerator 14, and measures at least one beam characteristic of a high energy ion beam accelerated by the plurality of linear accelerators 22a to 22c. The beam measurement unit 23 may be a measurement device that measures the beam characteristics such as beam energy, a beam current, a beam profile, and a beam angle.

In the present embodiment, three linear accelerators 22a to 22c are provided. The first linear accelerator 22a is provided in an upper stage of the beam accelerator 14, and includes a plurality of stages (for example, 5 to 15 stages) of the radio frequency accelerators. The first linear accelerator 22a performs “bunching” to align a continuous beam (DC beam) output from the ion generation device 12 with a specific acceleration phase, and accelerates the ion beam to have energy of approximately 1 MeV, for example. The second linear accelerator 22b is provided in a middle stage of the beam accelerator 14, and includes a plurality of stages (for example, 5 to 15 stages) of the radio frequency accelerators. The second linear accelerator 22b accelerates the ion beam output from the first linear accelerator 22a to have the energy of approximately 2 to 3 MeV, for example. The third linear accelerator 22c is provided in a lower stage of the beam accelerator 14, and includes a plurality of stages (for example, 5 to 15 stages) of the radio frequency accelerators. The third linear accelerator 22c accelerates the ion beam output from the second linear accelerator 22b to have the high energy of 4 MeV or higher, for example.

The high energy ion beam output from the beam accelerator 14 has an energy distribution in a certain range. Therefore, in order to irradiate the wafer with the high energy ion beam by performing reciprocating scanning and parallelizing on a downstream side of the beam accelerator 14, highly precise energy analysis, energy dispersion control, trajectory correction, and beam convergence/divergence adjustment need to be performed in advance.

The beam deflecting device 16 performs energy analysis, energy dispersion control, and trajectory correction of the high energy ion beam output from the beam accelerator 14. The beam deflecting device 16 forms a portion of the beamline BL extending in an arc shape. The high energy ion beam is deflected in a direction by the beam deflecting device 16 and is directed to the beam transport device 18.

The beam deflecting device 16 includes an energy analysis electromagnet 24, a horizontal focusing quadrupole lens 26 that suppresses energy dispersion, an energy resolving aperture 27, a first Faraday cup 28, a bending electromagnet 30 that provides steering (trajectory correction), and a second Faraday cup 31. The energy analysis electromagnet 24 is referred to as an energy filter electromagnet (EFM). In addition, a device group including the energy analysis electromagnet 24, the horizontal focusing quadrupole lens 26, the energy resolving aperture 27, and the first Faraday cup 28 is collectively referred to as an “energy analyzer”.

The energy resolving aperture 27 may be configured such that a slit width is variable to adjust resolution of energy analysis. For example, the energy resolving aperture 27 may be configured to include two blocking bodies that are movable in a slit width direction, and may be configured such that the slit width is adjustable by changing an interval between the blocking bodies. The energy resolving aperture 27 may be configured such that the slit width is variable by selecting any one of a plurality of slits having different slit widths.

The first Faraday cup 28 is disposed immediately after the energy resolving aperture 27, and is used for measuring a beam current for energy analysis. The second Faraday cup 31 is disposed immediately after the bending electromagnet 30, and is provided to measure the beam current of the ion beam which enters the beam transport device 18 after a trajectory the ion beam is corrected. Each of the first Faraday cup 28 and the second Faraday cup 31 is configured to be movable into and out of the beamline BL by an operation of a Faraday cup drive unit (not illustrated). Each of the first Faraday cup 28 and the second Faraday cup 31 may be a measurement device that measures beam characteristics such as a beam current, a beam profile, and a beam angle.

The beam transport device 18 forms another linearly extending portion in the beamline BL, and is parallel to the beam accelerator 14 with a maintenance region MA at the center of the ion implanter interposed therebetween. A length of the beam transport device 18 is designed to be approximately the same as a length of the beam accelerator 14. As a result, the beamline BL including the beam accelerator 14, the beam deflecting device 16, and the beam transport device 18 has a U-shaped layout as a whole.

The beam transport device 18 includes a beam shaper 32, a beam scanner 34, a beam dump 35, a beam parallelizer 36, a final energy filter 38, and left and right Faraday cups 39L and 39R.

The beam shaper 32 includes a convergence/divergence lens such as a quadrupole lens device (Q lens), and is configured to shape the ion beam passing through the beam deflecting device 16 into a desired cross-sectional shape. For example, the beam shaper 32 includes an electric field type three-stage quadrupole lens (also referred to as a triplet Q lens), and includes three lens devices 32a, 32b, and 32c. The beam shaper 32 can independently adjust convergence or divergence of the ion beam in each of a horizontal direction (x-direction) and a vertical direction (y-direction) by using the three lens devices 32a to 32c. The beam shaper 32 may include a magnetic field type lens device, or may include a lens device that shapes the beam by using both the electric field and the magnetic field.

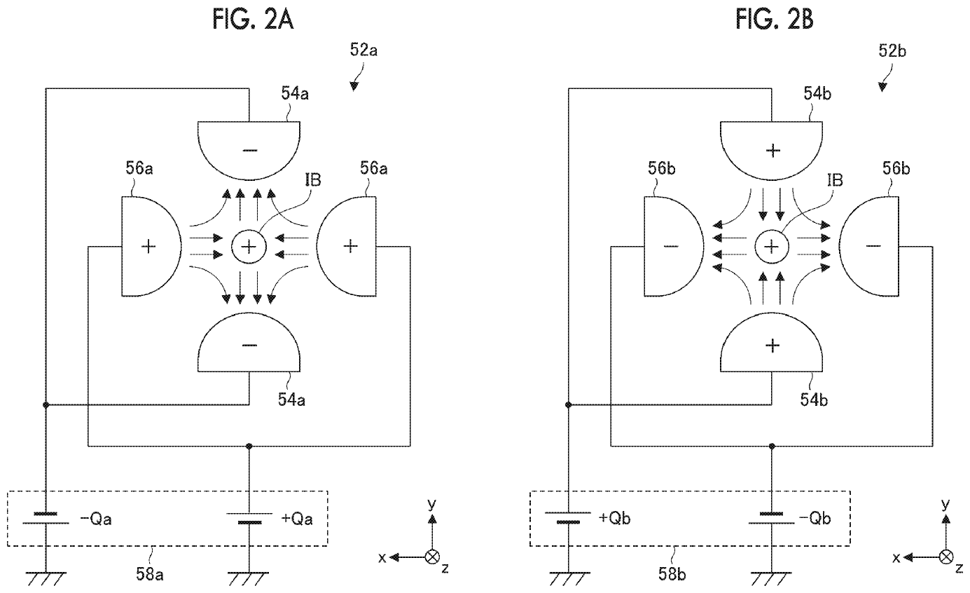

FIGS. 2A and 2B are front views illustrating a schematic configuration of the electrostatic quadrupole lens devices 52a and 52b. The electrostatic quadrupole lens device 52a in FIG. 2A is a horizontal convergence lens that causes the ion beam IB to converge in a horizontal direction (x-direction), and the electrostatic quadrupole lens device 52b in FIG. 2B is a vertical convergence lens that causes the ion beam IB to converge in a vertical direction (y-direction).

The electrostatic quadrupole lens device 52a in FIG. 2A includes a set of upper and lower lens electrodes 54a facing in the vertical direction (y-direction) and a set of left and right lens electrodes 56a facing in the horizontal direction (x-direction). A negative potential −Qa is applied to the upper and lower lens electrodes 54a, and a positive potential +Qa is applied to the left and right lens electrodes 56a. With respect to the ion beam IB including a positively charged ion, the electrostatic quadrupole lens device 52a generates an attractive force between the upper and lower lens electrodes 54a having the negative potential, and generates a repulsive force between the left and right lens electrodes 56a having the positive potential. In this manner, the electrostatic quadrupole lens device 52a adjusts the beam shape to cause the ion beam IB to converge in the x-direction and to diverge in the y-direction.

As in FIG. 2A, the electrostatic quadrupole lens device 52b in FIG. 2B includes a set of upper and lower lens electrodes 54b facing in the vertical direction (y-direction) and a set of left and right lens electrodes 56b facing in the horizontal direction (x-direction). In FIG. 2B, the applied positive and negative potentials are opposite to those in FIG. 2A, the positive potential +Qb is applied to the upper and lower lens electrodes 54b, and the negative potential −Qb is applied to the left and right lens electrodes 56b. As a result, the electrostatic quadrupole lens device 52b adjusts the beam shape to cause the ion beam IB to converge in the y-direction and to diverge in the x-direction.

For example, the electrostatic quadrupole lens device 52a in FIG. 2A can be used as a second lens device 32b of the beam shaper 32. For example, the electrostatic quadrupole lens device 52b in FIG. 2B can be used as a first lens device 32a and a third lens device 32c of the beam shaper 32.

Referring back to FIG. 1, the beam scanner 34 is a beam deflecting device configured to provide reciprocating scanning using the beam and to perform scanning using the shaped ion beam in the x-direction. The beam scanner 34 includes a scanning electrode pair facing in a beam scanning direction (x-direction). The scanning electrode pair is connected to a variable voltage power supply (not illustrated), and periodically changes a voltage applied between the scanning electrode pair. In this manner, the electric field generated between the electrodes is changed such that the ion beam is deflected at various angles. As a result, the ion beam is scanned over a scanning range indicated by an arrow X. In FIG. 1, a plurality of trajectories of the ion beam in the scanning range are indicated by a fine solid line. The beam scanner 34 may be replaced with another beam scan unit, and the beam scan unit may be configured to serve as a magnet device using the magnetic field.

The beam scanner 34 deflects the beam beyond the scanning range indicated by the arrow X to cause the ion beam to be incident into the beam dump 35 provided at a position away from the beamline BL. The beam scanner 34 causes the ion beam to temporarily retreat from the beamline BL toward the beam dump 35, thereby blocking the ion beam such that the ion beam does not reach the substrate transport process device 20 located downstream.

The beam parallelizer 36 is configured to cause a traveling direction of the scanning ion beam to be parallel to the trajectory of the designed beamline BL. The beam parallelizer 36 includes a plurality of arc-shaped parallelizing lens electrodes in which a passing slit of the ion beam is provided in a central portion. The parallelizing lens electrodes are connected to a high-voltage power supply (not illustrated), and applies the electric field generated by voltage application to the ion beam such that the traveling direction of the ion beam is parallelized. The beam parallelizer 36 may be replaced with another beam parallelizing device, and the beam parallelizing device may be configured to serve as a magnet device using the magnetic field.

The final energy filter 38 is configured to analyze energy of the ion beam and to deflect the ions having the required energy downward (in the −y-direction) such that the ions are guided to the substrate transport process device 20. The final energy filter 38 is sometimes referred to as an angular energy filter (AEF), and includes an AEF electrode pair for electric field deflection. The AEF electrode pair is connected to a high-voltage power supply (not illustrated). The ion beam is deflected downward by applying a positive voltage to an upper AEF electrode and applying a negative voltage to a lower AEF electrode. The final energy filter 38 may be configured to include a magnet device for magnetic field deflection, or may be configured to include a combination between the AEF electrode pair for electric field deflection and the magnet device for magnetic field deflection.

The left and right Faraday cups 39L and 39R are provided on the downstream side of the final energy filter 38, and are disposed at positions into which the beams at a left end and a right end of the scanning range indicated by the arrow X can be incident. The left and right Faraday cups 39L and 39R are provided at positions that do not block the beam toward a wafer W, and measure the beam current during ion implantation into the wafer W.

The substrate transport process device 20 is provided on the downstream side of the beam transport device 18, that is, a most downstream side of the beamline BL. The substrate transport process device 20 includes an implantation processing chamber 40, a beam monitor 41, a beam profiler 42, a profiler driving device 43, a substrate transport device 44, and a load port 46. The implantation processing chamber 40 is provided with a platen driving device (not illustrated) that holds the wafer W during the ion implantation and moves the wafer W in a direction (y-direction) perpendicular to the beam scanning direction (x-direction).

The beam monitor 41 is provided on the most downstream side of the beamline BL inside the implantation processing chamber 40. The beam monitor 41 is provided at a position into which the ion beam can be incident when the wafer W is not present on the beamline BL, and is configured to measure the beam characteristic before or during the ion implantation process. The beam monitor 41 may be a measurement device that measures the beam characteristics such as the beam current, the beam current density distribution, the beam angle, and the beam parallelism. For example, the beam monitor 41 is located close to a transport port (not illustrated) connecting the implantation processing chamber 40 and the substrate transport device 44, and is provided at a position vertically below the transport port.

The beam profiler 42 is configured to measure the beam current at a position on a surface of the wafer W. The beam profiler 42 is configured to be movable in the x-direction by an operation of the profiler driving device 43, is retracted from an implantation position where the wafer W is located during the ion implantation, and is inserted into the implantation position when the wafer W is not located at the implantation position. The beam profiler 42 measures the beam current while moving in the x-direction. In this manner, the beam profiler 42 can measure the beam current over the entire beam scanning range in the x-direction. In the beam profiler 42, a plurality of Faraday cups may be aligned in an array shape in the x-direction such that the beam currents can be simultaneously measured at a plurality of positions in the beam scanning direction (x-direction). The beam profiler 42 may be a measurement device that measures the beam current density distribution in the x-direction.

The beam profiler 42 may include a single Faraday cup for measuring the beam current, or may include an angle measurement device for measuring angle information of the beam. For example, the angle measurement device includes a slit and a plurality of current detection units provided away from the slit in the beam traveling direction (z-direction). For example, the angle measurement device can measure an angle component of the beam in a slit width direction by causing the plurality of current detection units aligned in the slit width direction to measure the beams passing through the slit. The beam profiler 42 may include a first angle measurement device which can measure angle information in the x-direction and a second angle measurement device which can measure the angle information in the y-direction. The beam profiler 42 may be a measurement device that measures the beam angle in the x-direction and the beam angle in the y-direction. The beam profiler 42 may measure the angle center of gravity or a convergence/divergence angle, as the angle information of the beam.

The substrate transport device 44 is configured to transport the wafer W between the load port 46 on which a wafer container 45 is placed and the implantation processing chamber 40. The load port 46 is configured such that a plurality of the wafer containers 45 can be simultaneously placed, and for example, has four mounting tables aligned in the x-direction. A wafer container transport port (not illustrated) is provided vertically above the load port 46, and is configured such that the wafer container 45 can pass in the vertical direction. For example, the wafer container 45 is automatically loaded into the load port 46 through the wafer container transport port by a transport robot installed on a ceiling inside a semiconductor manufacturing factory where the ion implanter 100 is installed, and is automatically unloaded from the load port 46.

The ion implanter 100 further includes a central control device 50. The central control device 50 controls an overall operation of the ion implanter 100. The central control device 50 is realized by an element and a machine device such as a computer CPU and a memory in terms of hardware, and is realized by a computer program in terms of software. Various functions provided by the central control device 50 can be realized in cooperation between the hardware and the software.

An operation panel 49 having a display unit and an input device for setting the operation parameter of the ion implanter 100 is provided in the vicinity of the central control device 50. Positions of the operation panel 49 and the central control device 50 are not particularly limited. However, for example, the operation panel 49 and the central control device 50 can be disposed adjacent to an inlet and outlet 48 of the maintenance region MA between the ion generation device 12 and the substrate transport process device 20. Work efficiency can be improved by adjoining locations of the ion source 10, the load port 46, the operation panel 49, and the central control device 50 which are frequently operated by an operator who manages the ion implanter 100.

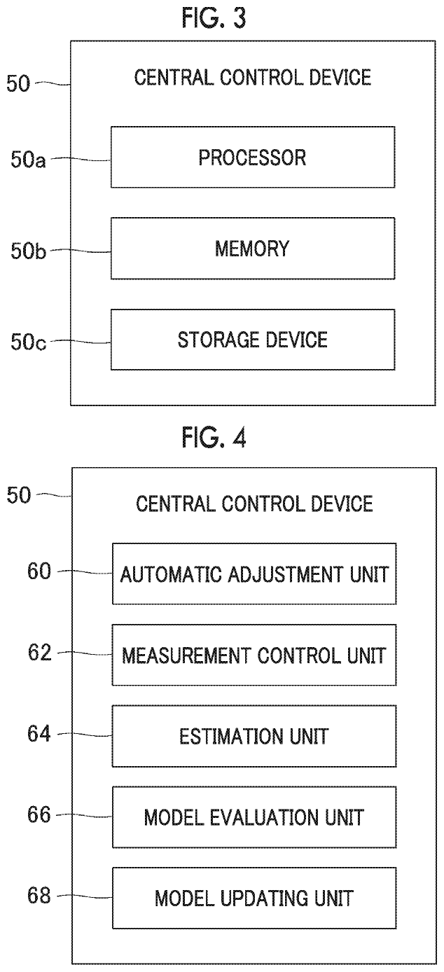

FIG. 3 is a diagram schematically illustrating a configuration of the central control device 50. The central control device 50 includes a processor 50a such as a central processing unit (CPU), a memory 50b such as a read only memory (ROM) or a random access memory (RAM), and a recording device 50c such as a hard disk drive (HDD) or a solid state drive (SSD).

For example, the central control device 50 causes the processor 50a to execute a program stored in the memory 50b to control an overall operation of the ion implanter 100 in accordance with the program. The processor 50a may execute a program stored in any storage device different from the memory 50b, may execute a program acquired from any recording medium by a reading device, or may execute a program acquired via a network. The memory 50b storing the program may be a volatile memory such as a dynamic random access memory (DRAM), or may be a non-volatile memory such as an electrically erasable programmable read-only memory (EEPROM), a flash memory, a magnetic resistance memory, a variable resistance type memory, or a ferroelectric memory. A magnetic recording medium such as the non-volatile memory, a magnetic tape, and a magnetic disk, and an optical recording medium such as an optical disk are examples of a non-transitory and tangible computer readable recording medium (storage medium).

Various functions provided by the central control device 50 may be realized by a single device including the processor 50a and the memory 50b, or may be realized by cooperation of a plurality of devices each including the processor 50a and the memory 50b. The recording device 50c records data indicating the actual operation results of the ion implanter 100. The recording device 50c may be provided in the central control device 50, or may be provided as an external device separate from the central control device 50.

FIG. 4 is a block diagram schematically illustrating a functional configuration of the central control device 50. The central control device 50 includes an automatic adjustment unit 60, a measurement control unit 62, an estimation unit 64, a model evaluation unit 66, and a model updating unit 68. Each functional block illustrated in FIG. 4 is realized by causing the processor 50a to execute the program stored in the memory 50b.

The automatic adjustment unit 60 executes an automatic adjustment program for adjusting the plurality of operation parameters, and adjusts the plurality of operation parameters to realize a desired beam characteristic. The measurement control unit 62 controls an operation of the measurement device, and acquires a measurement value of at least one beam characteristic of the ion beam. The estimation unit 64 calculates an estimated value of the beam characteristic from a setting value of at least one operation parameter by using a model indicating a correlation between at least one operation parameter and the beam characteristic. The model evaluation unit 66 evaluates validity of the model used in the estimation unit 64 by comparing the measurement value and the estimated value of the beam characteristic. When the model evaluation unit 66 evaluates that the model is not valid, the model updating unit 68 updates the model by using the measurement value and the estimated value of the beam characteristic. For example, data of the model used for estimating the beam characteristic is stored in the memory 50b or the recording device 50c.

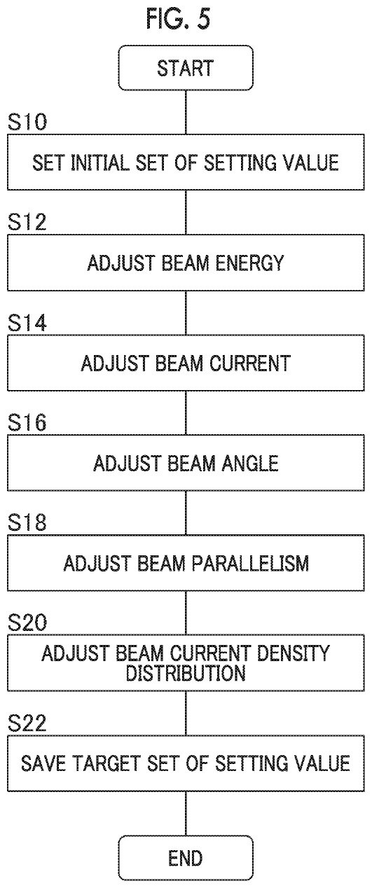

FIG. 5 is a flowchart illustrating an example of a method for adjusting the operation parameter. First, a set (also referred to as an initial set) of setting values of the plurality of operation parameters is set (S10). Subsequently, a plurality of beam characteristics of the ion beam are adjusted (S12 to S20). In an example in FIG. 5, beam energy (S12), a beam current (S14), a beam angle (S16), a beam parallelism (S18), and a beam current density distribution (S20) are sequentially adjusted. Finally, a set (also referred to as a target set) of the setting values of the plurality of operation parameters when the adjustment is completed is saved (S22). The order of adjustment in S12 to S20 is not limited, and the order of adjustment may be changed as appropriate. In addition, adjustment of a specific beam characteristic may be performed multiple times. For example, a second beam characteristic may be adjusted after a first beam characteristic is adjusted. Thereafter, the first beam characteristic may be adjusted again.

In S10, for example, an initial set according to a target beam characteristic is determined. The automatic adjustment unit 60 may determine the initial set by performing a simulation using a predetermined algorithm. The automatic adjustment unit 60 may determine the initial set, based on a set of past setting values stored in the recording device 50c. For example, when there is a set of the past setting values in which the ion beam having the beam characteristic coinciding with or approximating the target beam characteristic is obtained, the setting value of the operation parameter included in the set may be used as at least a part of the initial set.

In adjusting the beam energy in S12, the operation parameters of the ion generation device 12 and the beam accelerator 14 are adjusted. Specifically, the beam energy is adjusted by adjusting the operation parameters such as an extraction voltage of the ion source 10, and an amplitude, a frequency, and a phase of a radio frequency voltage V_{RF} applied to each of the radio frequency accelerators in a plurality of stages included in the beam accelerator 14. For example, the beam energy is measured by the beam measurement unit 23.

In adjusting the beam current in S14, the operation parameters of the ion generation device 12 and the beam deflecting device 16 are adjusted. Specifically, the beam current is adjusted by adjusting the operation parameters such as a source gas flow rate, an arc current, an arc voltage and a source magnet current of the ion source 10, and a slit opening width of the mass resolving aperture 11b and the energy resolving aperture 27. For example, the beam current is measured by the beam measurement unit 23, the first Faraday cup 28, the second Faraday cup 31, the beam monitor 41, or the beam profiler 42.

In adjusting the beam angle in S16, the operation parameters of the beam deflecting device 16 and the beam transport device 18 are adjusted. For example, a center of gravity of the beam angle in the x-direction is adjusted by a magnet current of the bending electromagnet 30. The center of gravity of the beam angle in the y-direction is adjusted by an applied voltage of the final energy filter 38. The convergence/divergence angles in the x-direction and the y-direction are adjusted by the applied voltages of the lens devices 32a to 32c included in the beam shaper 32. A beam size in the x-direction and the y-direction may be adjusted by adjusting the applied voltages of the lens devices 32a to 32c. For example, the beam angle and the beam size in the x-direction and the y-direction are measured by the beam monitor 41 or the beam profiler 42.

In adjusting the beam parallelism in S18, the operation parameter of the beam transport device 18 is adjusted. Specifically, the beam parallelism is adjusted by adjusting the applied voltage of the parallelizing lens electrode included in the beam parallelizer 36. For example, the beam parallelism is measured by the beam monitor 41 or the beam profiler 42.

In adjusting the beam current density distribution in S20, the operation parameter of the beam transport device 18 is adjusted. Specifically, the beam current density distribution in the x-direction is adjusted by adjusting a voltage waveform applied to the scanning electrode pair included in the beam scanner 34. For example, the beam current density distribution is measured by the beam monitor 41 or the beam profiler 42.

In the adjustment processes in S12 to S20, for example, the beam characteristic to be adjusted is measured, and at least one operation parameter is adjusted, based on a measurement value of the measured beam characteristic. The measurement control unit 62 operates the measurement device to acquire the measurement value of the beam characteristic to be adjusted. When the measurement value of the beam characteristic satisfies a desired condition, the automatic adjustment unit 60 completes adjusting the beam characteristic to be adjusted. When the measurement value of the beam characteristic does not satisfy the desired condition, the automatic adjustment unit 60 adjusts a setting value of the operation parameter such that the beam characteristic satisfies the desired condition.

In the adjustment processes in S12 to S20, instead of measuring the beam characteristic to be adjusted, an estimated value of the beam characteristic may be calculated, and at least one operation parameter may be adjusted, based on the estimated value of the beam characteristic. The estimation unit 64 calculates the estimated value of at least one beam characteristic by using the model. When the estimated value of the beam characteristic satisfies the desired condition, the automatic adjustment unit 60 may skip the measurement of the beam characteristic to be adjusted, and may complete adjusting the beam characteristic to be adjusted. When the estimated value of the beam characteristic does not satisfy the desired condition, the automatic adjustment unit 60 may adjust at least one operation parameter by using the model. For example, a value of the operation parameter may be calculated by using the model such that the estimated value of the beam characteristic satisfies the desired condition. When the estimated value of the beam characteristic acquired from the estimation unit 64 does not satisfy the desired condition, the automatic adjustment unit 60 may adjust the setting value of the operation parameter, based on the estimated value. When the operation parameter based on the estimated value is not successfully adjusted, the automatic adjustment unit 60 may adjust the operation parameter, based on the measurement value.

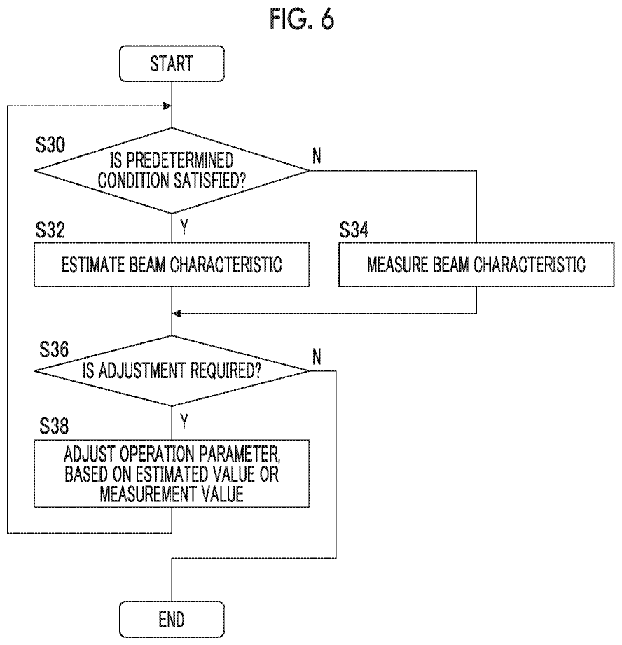

FIG. 6 is a flowchart illustrating an example of a method for adjusting the beam characteristic. FIG. 6 illustrates details of a process of adjusting one beam characteristic in each of S12 to S20 in FIG. 5. When a predetermined condition is satisfied (Y in S30), the beam characteristic to be adjusted is estimated by using the model (S32). When the predetermined condition is not satisfied (N in S30), the beam characteristic to be adjusted is measured by using the measurement device (S34). Here, the predetermined condition in S30 may include various conditions. The predetermined condition is satisfied when a model for estimating the beam characteristic to be adjusted is present, when a model used for estimated is valid, and when the number of adjustments based on the estimated value is smaller than a predetermined number, and the like. When it is necessary to adjust the estimated or measured beam characteristic (Y in S36), the operation parameter is adjusted, based on the estimated value or the measurement value of the beam characteristic (S38), and the process returns to S30. When it is not necessary to adjust the beam characteristic in S36 (N in S36), the flow ends.

As an example of a flow in FIG. 6, when the predetermined condition is satisfied in S30, the operation parameter is adjusted, based on the estimated value of the beam characteristic. When the estimated value of the beam characteristic satisfies the desired condition, the operation parameter is completely adjusted. In this case, the measurement of the beam characteristic is skipped in the adjustment process of the beam characteristic. Therefore, a time required for the measurement of the beam characteristic can be shortened. On the other hand, when the predetermined condition is not satisfied in S30, the operation parameter is adjusted, based on the measurement value of the beam characteristic. When the measurement value of the beam characteristic satisfies the desired condition, the operation parameter is completely adjusted. For example, by measuring the beam characteristic when the estimated value of the beam characteristics is not valid or when the number of adjustments based on the estimated value of the beam characteristic reaches a predetermined number of times, the operation parameter can more reliably be adjusted based on the measurement value.

The model evaluation unit 66 evaluates the validity of the model. The model evaluation unit 66 evaluates the validity of the model by comparing the measurement value and the estimated value of the beam characteristic. The model evaluation unit 66 compares the measurement value measured when a specific operation parameter is set and the estimated value when the specific operation parameter is input to the model. For example, the model evaluation unit 66 evaluates that the model is valid when a difference between the measurement value and the estimated value is smaller than a predetermined threshold, and evaluates that the model is not valid when the difference between the measurement value and the estimated value is equal to or greater than the predetermined threshold. For example, a magnitude of the threshold can be appropriately set for each beam characteristic in accordance with accuracy required for the beam characteristic.

The model evaluation unit 66 may evaluate the validity of the model by using a plurality of the measurement values and a plurality of the estimated values. The model evaluation unit 66 may compare the plurality of measurement values and the plurality of estimated values, and may evaluate the validity of the model, based on consistency between the plurality of measurement values and the plurality of estimated values. The model evaluation unit 66 may evaluate the validity of the model by comparing an extremum calculated from the plurality of measurement values and an extremum calculated from the plurality of estimated values, when the beam characteristic has the extremum (maximum value or minimum value), with respect to a change in the setting value of at least one operation parameter. In this case, the model evaluation unit 66 determines a range in which the extremum of the beam characteristic is present in the model, the automatic adjustment unit 60 changes the setting value of at least one operation parameter in the determined range, the measurement control unit 62 measures the beam characteristic to acquire the measurement value, and the estimation unit 64 calculates the estimated value of the beam characteristic. In this manner, the model evaluation unit 66 can compare the extremum of the plurality of measurement values and the extremum of the plurality of estimated values.

When the model evaluation unit 66 evaluates that the model is not valid, the model updating unit 68 updates the model by using the measurement value and the estimated value of the beam characteristic. The model updating unit 68 updates the model such that the estimated value of at least one operation parameter estimated from the updated model coincides with the measurement value of the beam characteristic, or a difference therebetween is minimized. The model updating unit 68 may update the model by linearly transforming the setting value of at least one operation parameter, for example, by adding a constant to or multiplying the setting value of at least one operation parameter by a constant. The model updating unit 68 may update the model by linearly transforming the estimated value of the beam characteristic, for example, by adding a constant to or multiplying the estimated value of the beam characteristic by a constant. The model updating unit 68 may update the model such that the extremum of the measurement value of the beam characteristic and the extremum of the estimated value of the beam characteristic coincide with each other, when the measurement value of the beam characteristic has the extremum and the estimated value of the beam characteristic has the extremum in the model. When the model evaluation unit 66 evaluates that the model is valid, the model updating unit 68 may not update the model.

When the model is updated, the automatic adjustment unit 60 can determine a target set of the setting values of at least one operation parameter for generating the ion beam that satisfies a desired beam characteristic, by using the updated model. By using an appropriately updated model, the automatic adjustment unit 60 can generate the ion beam that satisfies the desired beam characteristic, by using the target set as is. In this case, a time required for the beam adjustment can be significantly shortened, and the beam characteristic can be highly accurately adjusted.

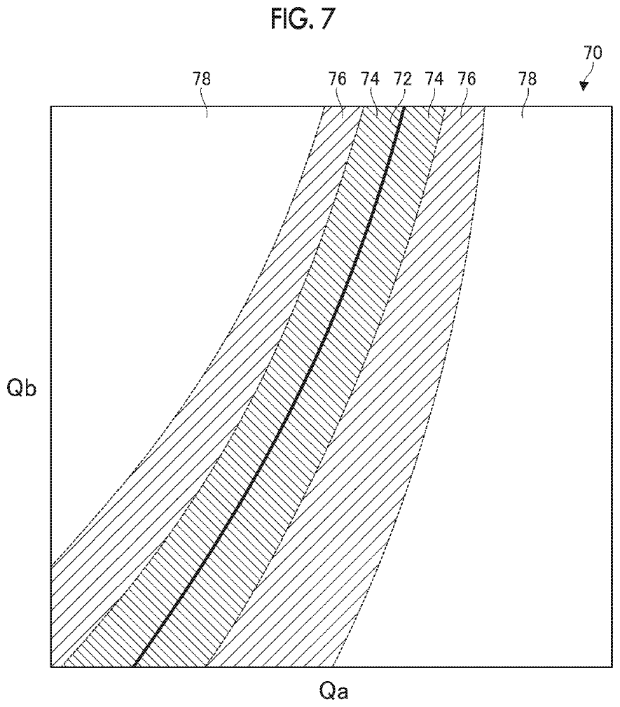

FIG. 7 is a diagram schematically illustrating an example of a model 70 indicating a correlation between the setting value of the plurality of operation parameters and one beam characteristic. FIG. 7 illustrates the model 70 when the plurality of operation parameters are the applied voltages of the lens devices 32a to 32c and one beam characteristic is a beam width in the x-direction. For example, the first operation parameter illustrated on a horizontal axis is a first potential Qa applied to the first lens device 32a and the third lens device 32c, and for example, the second operation parameter illustrated on a vertical axis is a second potential Qb applied to the second lens device 32b.

In the model 70 illustrated in FIG. 7, the beam width in the x-direction, which is the beam characteristic, takes a minimum value at a position of a thick line 72, and a value increases as the position is separated from the thick line 72. A target region 74 adjacent to the thick line 72 is a region where the beam width in the x-direction falls within a target value range. An allowable region 76 outside a target region 74 is a region where the beam width in the x-direction is greater than the target value but is equal to or smaller than an allowable value. A non-allowable region 78 outside the allowable region 76 is a region where the beam width in the x-direction is greater than the allowable value. When the beam width in the x-direction is adjusted, setting values Qa and Qb of the plurality of operation parameters are adjusted such that the value of the beam width in the x-direction falls within the target value range or is equal to or smaller than the allowable value, that is, such that the value of the beam width in the x-direction is included in the target region 74 or the allowable region 76.

When the validity of the model 70 is evaluated, the model evaluation unit 66 determines a plurality of sets of the setting values of the plurality of operation parameters used for the evaluation. Here, a set of the setting values of the plurality of operation parameters means a combination of the setting values Qa and Qb of the plurality of operation parameters, and corresponds to a coordinate point (Qa and Qb) defined by the combination of the setting values of the plurality of operation parameters. The model evaluation unit 66 determines a plurality of the coordinate points defined by each of the plurality of sets in order to evaluate the model 70.

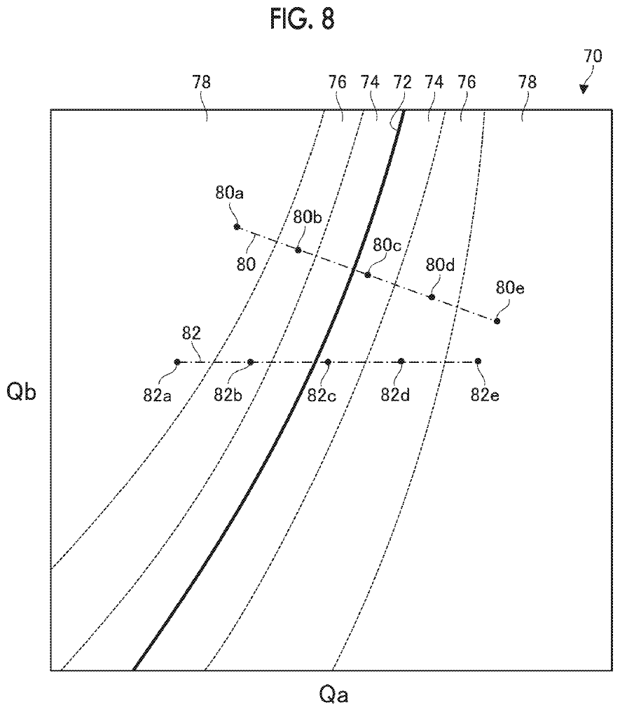

FIG. 8 is a diagram schematically illustrating the plurality of sets of the setting values of the plurality of operation parameters set on the model 70. The plurality of coordinate points 80a to 80e or 82a to 82e corresponding to the plurality of sets are set along a line segment 80 or 82 drawn on the model 70. The line segment 80 or 82 is set to intersect the thick line 72 indicating the extremum of the beam characteristic. The first line segment 80 indicates a case where the first line segment 80 is set to be perpendicular to the thick line 72 indicating the extremum. The second line segment 82 indicates a case where the second line segment 82 is set to obliquely intersect the thick line 72 indicating the extremum. The second line segment 82 can be set such that at least one of the plurality of operation parameters has a fixed value. In an example in FIG. 8, the second line segment 82 is set such that the setting value Qb of the second operation parameter is constant.

Three or more of the plurality of coordinate points 80a to 80e or 82a to 82e corresponding to the plurality of sets can be set on the line segments 80 or 82. Since at least three coordinate points are set, it is possible to calculate a position of the extremum of the beam characteristic from the measurement value or the estimated value of the beam characteristic corresponding to at least three coordinate points. For example, since a polynomial (for example, a quadratic function) having the extremum with respect to the measurement value or the estimated value of the beam characteristic corresponding to the plurality of coordinate points is fitted, the extremum in the fitted polynomial can be regarded as the extremum of the beam characteristic. Since the line segment 80 or 82 is set to intersect the thick line 72 indicating the extremum, the plurality of sets can be set such that the extremum of the measurement value and the estimated value of the first beam characteristic is present in the range including the plurality of coordinate points 80a to 80e or 82a to 82e. It is preferable that the length of the line segment 80 or 82 corresponding to the range in which the plurality of coordinate points are set is sufficiently long to be suitable for the calculation of the extremum. For example, it is preferable that each of both ends of the line segment 80 or 82 is located in the allowable region 76 or the non-allowable region 78.

The model evaluation unit 66 can evaluate the validity of the model by using the plurality of measurement values of the beam characteristic measured when each of the plurality of sets is set and the plurality of estimated values of the beam characteristic estimated by using the model from each of the plurality of sets. The model evaluation unit 66 may compare the plurality of measurement values and the plurality of estimated values, and may evaluate the validity of the model, based on the consistency between the plurality of measurement values and the plurality of estimated values. The model evaluation unit 66 may compare the extremum of the measurement value calculated from the plurality of measurement values and the extremum of the estimated value calculated from the plurality of estimated values, and may evaluate the validity of the model, based on the consistency of the extrema. For example, the first set of the setting values corresponding to the extremum of the measurement value and the second set of the setting values corresponding to the extremum of the estimated value may be compared, and the validity of the model may be evaluated, based on the consistency between the first set and the second set. For example, the consistency between the first set and the second set can be evaluated by using a distance between a first coordinate point corresponding to the first set and a second coordinate point corresponding to the second set.

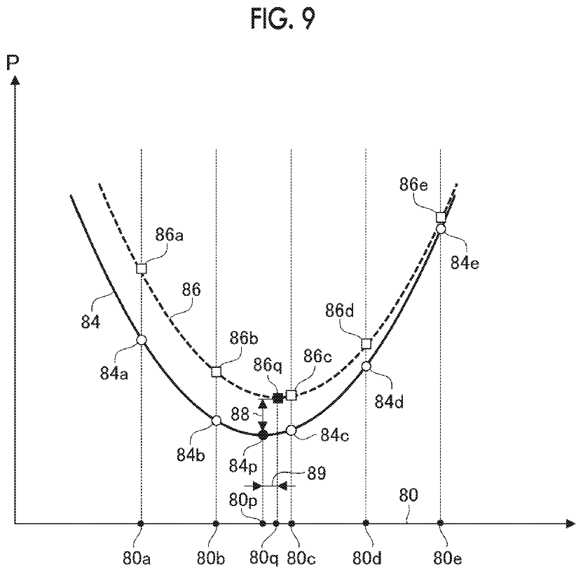

FIG. 9 is a diagram schematically illustrating an example of a method for evaluating the validity of the model. FIG. 9 illustrates a case where the plurality of coordinate points 80a to 80e corresponding to the plurality of sets are set on the first line segment 80 illustrated in FIG. 8. Plots 84a to 84e illustrated in FIG. 9 indicate the plurality of measurement values of the beam characteristic (that is, the beam width in the x-direction) measured when each of the plurality of sets is set. Plots 86a to 86e illustrated in FIG. 9 indicate the plurality of estimated values of the beam characteristic (that is, the beam width in the x-direction) estimated by using the model from each of the plurality of sets. A curve 84 is a quadratic function fitted to the plots 84a to 84e of the plurality of measurement values. An extremum 84p of the measurement value can be calculated by using the curve 84, and a coordinate point 80p indicating the first set of the setting values corresponding to the extremum 84p of the measurement value can be calculated. A curve 86 is a quadratic function fitted to the plots 86a to 86e of the plurality of estimated values. An extremum 86q of the estimated value can be calculated by using the curve 86, and a coordinate point 80q indicating the second set of the setting values corresponding to the extremum 86q of the estimated value can be calculated. The model evaluation unit 66 can evaluate the validity of the model by using a difference 88 between the extremum 84p of the measurement value and the extremum 86q of the estimated value. The model evaluation unit 66 can evaluate the validity of the model by using a distance 89 between the coordinate point 80p indicating the first set of the setting values and the coordinate point 80q indicating the second set of the setting values.

The model updating unit 68 can update the model such that the updated model coincides with the curve 84 fitted to the plots 84a to 84e of the plurality of measurement values. For example, the curve 86 fitted to the plots 86a to 86e of the plurality of estimated values can be linearly transformed, and the model can be updated such that the linearly transformed curve coincides with the curve 84. Specifically, the model can be updated by multiplying a constant by the curve 86 to expand or contract the model, or by adding a constant to the curve 86 to move the model in parallel.

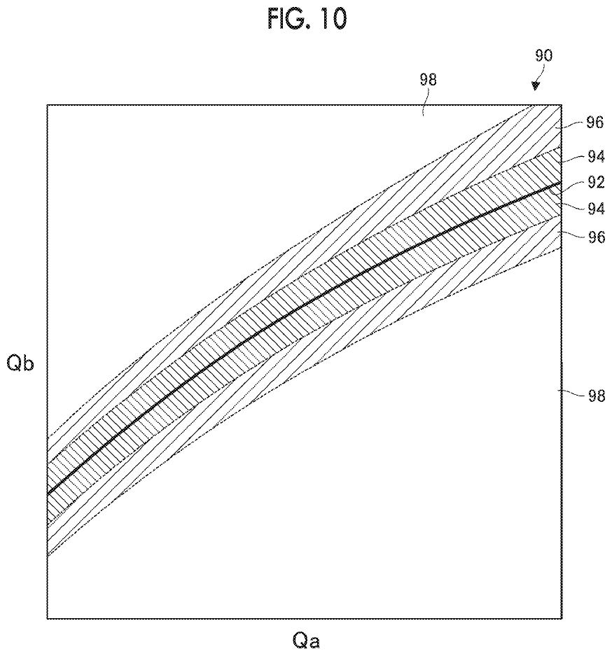

FIG. 10 is a diagram schematically illustrating an example of the model indicating a correlation between the setting value of the plurality of operation parameters and one beam characteristic. FIG. 10 illustrates a model 90 when the plurality of operation parameters are the applied voltages Qa and Qb of the lens devices 32a to 32c and one beam characteristic is the beam width in the y-direction. The model 70 in FIG. 7 can be referred to as a first model for estimating the beam width in the x-direction, which is the first beam characteristic, and the model 90 in FIG. 10 can be referred to as a second model for estimating the beam width in the y-direction, which is the second beam characteristic. The first model 70 in FIG. 7 and the second model 90 in FIG. 10 estimate the first beam characteristic and the second beam characteristic when the first operation parameter Qa and the second operation parameter Qb which are common to each other are input.

In the second model 90 illustrated in FIG. 10, the beam width in the y-direction, which is the second beam characteristic, takes a minimum value at a position of a thick line 92, and increases as the position is separated from the thick line 92. A target region 94 adjacent to the thick line 92 is a region where the beam width in the y-direction falls within the target value range. An allowable region 96 outside the target region 94 is a region where the beam width in the y-direction is greater than the target value but is equal to or smaller than the allowable value. A non-allowable region 98 outside the allowable region 96 is a region where the beam width in the y-direction is greater than the allowable value. When the beam width in the y-direction is adjusted, the setting values Qa and Qb of the plurality of operation parameters are adjusted such that the value of the beam width in the y-direction falls within the target value range or is equal to or smaller than the allowable value, that is, such that the value of the beam width in the y-direction is included in the target region 94 or the allowable region 96.

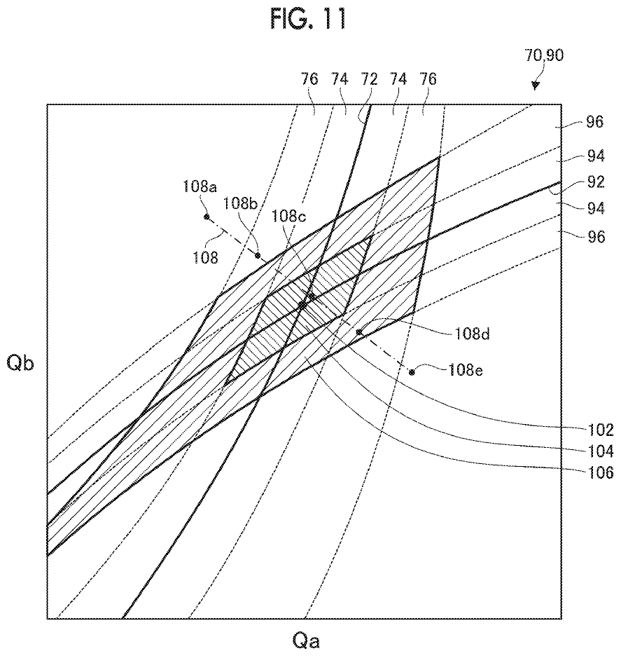

FIG. 11 is a diagram schematically illustrating a method for determining the target set of the setting values of the plurality of operation parameters by using a plurality of models. FIG. 11 illustrates a state where the first model 70 illustrated in FIG. 7 and the second model 90 illustrated in FIG. 10 overlap each other. Normally, it is required that both the beam width in the x-direction, which is the first beam characteristic, and the beam width in the y-direction, which is the second beam characteristic, simultaneously fall within the target value range or be equal to or smaller than the allowable value. In that case, the target set may be determined within a target region 104 or within an allowable region 106 in the vicinity of an intersection point 102 of the thick line 72 indicating the extremum of the first beam characteristic in the first model 70 and the thick line 92 indicating the extremum of the second beam characteristic in the second model 90. The target region 104 illustrated in FIG. 11 is a range in which the target region 74 in FIG. 7 and the target region 94 in FIG. 10 overlap each other. The allowable region 106 illustrated in FIG. 11 is a range in which the allowable region 76 in FIG. 7 and the allowable region 96 in FIG. 10 overlap each other.

The model evaluation unit 66 can determine a plurality of common sets of the setting values of the plurality of operation parameters used for the evaluation in order to simultaneously evaluate the validity of each of the first model 70 and the second model 90. For example, as illustrated in FIG. 11, a plurality of coordinate points 108a to 108e corresponding to the plurality of common sets can be set along a line segment 108. The line segment 108 is set to intersect both the thick line 72 indicating the extremum of the first beam characteristic and the thick line 92 indicating the extremum of the second beam characteristic. The line segment 108 is set to intersect the target region 104 and the allowable region 106. It is preferable that the length of the line segment 108 corresponding to a range in which the plurality of coordinate points are set is sufficiently long to be suitable for the calculation of the extremum. For example, it is preferable that each of both ends of the line segment 108 is located in the allowable region 106 or is located outside the allowable region 106. Since the plurality of common sets are set, each of the first model 70 and the second model 90 can be simultaneously evaluated.

The model evaluation unit 66 can evaluate the validity of the first model 70 by using the plurality of first measurement values of the first beam characteristic when each of the plurality of common sets is set and the plurality of first estimated values of the first beam characteristic estimated by using the first model 70 from each of the plurality of common sets. The model evaluation unit 66 may evaluate the validity of the first model 70 by using the extremum of the first measurement value calculated from the plurality of first measurement values and the extremum of the first estimated value calculated from the plurality of first estimated values. The model evaluation unit 66 may evaluate the validity of the first model 70 by comparing the first set of the setting values corresponding to the extremum of the first measurement value and the second set of the setting values corresponding to the extremum of the first estimated value. The model evaluation unit 66 can evaluate the validity of the second model 90 by using the plurality of second measurement values of the second beam characteristic when each of the plurality of common sets is set and the plurality of second estimated values of the second beam characteristic estimated by using the second model 90 from each of the plurality of common sets. The model evaluation unit 66 may evaluate the validity of the second model 90 by using the extremum of the second measurement value calculated from the plurality of second measurement values and the extremum of the second estimated value calculated from the plurality of second estimated values. The model evaluation unit 66 may evaluate the validity of the second model 90 by comparing a third set of the setting values corresponding to the extremum of the second measurement value and a fourth set of the setting values corresponding to the extremum of the second estimated value.

The model updating unit 68 may update at least one of the first model 70 and the second model 90 by using the plurality of common sets. The model updating unit 68 can update the first model 70 by using the plurality of first measurement values of the first beam characteristic when each of the plurality of common sets is set and the plurality of first estimated values of the first beam characteristic estimated by using the first model 70 from each of the plurality of common sets. The model updating unit 68 can update the second model 90 by using the plurality of second measurement values of the second beam characteristic when each of the plurality of common sets is set and the plurality of second estimated values of the second beam characteristic estimated by using the second model 90 from each of the plurality of common sets.

In order to evaluate the validity of each of the plurality of models when the plurality of common operation parameters are input, the model evaluation unit 66 may determine the plurality of sets of the setting values of the plurality of operation parameters used for the evaluation. For example, the model evaluation unit 66 can simultaneously evaluate a third model and a fourth model for estimating the convergence/divergence angle in the x-direction and the y-direction, in addition to the first model and the second model for estimating the beam size in the x-direction and the y-direction. For example, the third model is used to estimate the convergence/divergence angle in the x-direction, which is a third beam characteristic, when the first operation parameter Qa and the second operation parameter Qb are input. For example, the fourth model is used to estimate the convergence/divergence angle in the y-direction, which is a fourth beam characteristic, when the first operation parameter Qa and the second operation parameter Qb are input.

FIGS. 7 to 11 illustrate an example in which the beam characteristic has a minimum value with respect to a change in the operation parameter. However, the beam characteristic may have a maximum value with respect to the change in the operation parameter. In addition, FIGS. 7 to 11 illustrate an example in which the beam characteristic has an extremum with respect to a change in the two operation parameters. However, the beam characteristic may have an extremum with respect to a change in one, three, or more operation parameters. In addition, FIGS. 7 to 11 illustrate an example in which the beam characteristic has a linear extremum with respect to a change in two operation parameters. However, the beam characteristic may have a spot-shaped extremum with respect to a change in the two operation parameters.

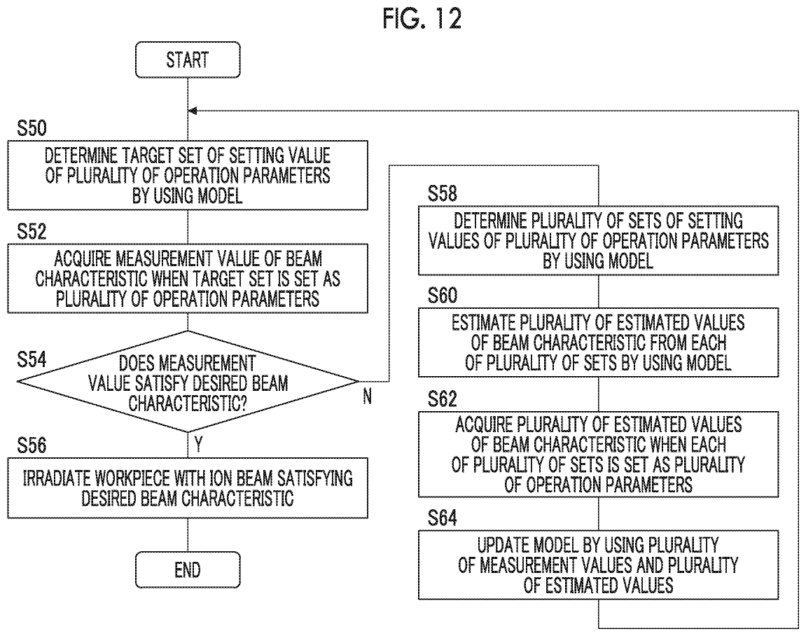

FIG. 12 is a flowchart illustrating an example of an ion implantation method according to an embodiment. The automatic adjustment unit 60 determines a target set of the setting values of the plurality of operation parameters for generating the ion beam that satisfies the desired beam characteristic, by using the model for estimating the beam characteristic (S50). The measurement control unit 62 measures the beam characteristic when the target set is set as the plurality of operation parameters, and acquires the measurement value (S52). When the measurement value satisfies the desired beam characteristic (Y in S54), the workpiece is irradiated with the ion beam that satisfies the desired beam characteristic (S56).

When the measurement value does not satisfy the desired beam characteristic (N in S54), the model evaluation unit 66 determines a plurality of sets of the setting values of the plurality of operation parameters using the model (S58). The estimation unit 64 estimates a plurality of estimated values of the beam characteristic from each of the plurality of sets by using the model (S60). The measurement control unit 62 measures the beam characteristic when each of the plurality of sets of the plurality of operation parameters is set, and acquires a plurality of measurement values (S62). The model updating unit 68 updates the model using a plurality of measurement values and a plurality of estimated values (S64). Thereafter, the processing of S50 to S56 is executed by using the updated model.

Hitherto, the present invention has been described with reference to the above-described respective embodiments. However, the present invention is not limited to the above-described respective embodiments. Those in which configurations of the respective embodiments are appropriately combined or replaced with each other are also included in the present invention. Based on the knowledge of those skilled in the art, the respective embodiments can be combined with each other, the processing sequences can be appropriately rearranged, or various modifications such as design changes can be added to the embodiment. The embodiment having the added modifications can also be included in the scope of the present invention.

According to an aspect of the present invention, the operation parameter can be quickly and accurately adjusted.

It should be understood that the invention is not limited to the above-described embodiment, but may be modified into various forms on the basis of the spirit of the disclosure. Additionally, the modifications are included in the scope of the disclosure.

What is claimed is:

1. An ion implanter comprising:
a beam generation device configured to operate in accordance with a plurality of operation parameters to generate an ion beam;
an implantation processing chamber in which a workpiece is irradiated with the ion beam;
a measurement device that measures a beam characteristic of the ion beam;
a memory that stores a model for estimating the beam characteristic from a set of setting values of the plurality of operation parameters, and a predetermined program; and
a processor that executes the predetermined program,
wherein in accordance with the predetermined program,
the processor updates the model by using a plurality of measurement values of the beam characteristic measured when each of a plurality of sets of the setting values of the plurality of operation parameters is set as the plurality of operation parameters, and a plurality of estimated values of the beam characteristic estimated by using the model from each of the plurality of sets, and
the processor determines a target set of the setting values of the plurality of operation parameters for generating an ion beam which satisfies a desired beam characteristic by using the updated model.

2. The ion implanter according to claim 1,
wherein in accordance with the predetermined program,
the processor updates the model such that the beam characteristic estimated from the updated model coincides with the plurality of measurement values within a range including the plurality of sets.

3. The ion implanter according to claim 1,
wherein in accordance with the predetermined program,
the processor updates the model by linearly transforming the setting value of at least one operation parameter of the plurality of operation parameters.

4. The ion implanter according to claim 1,
wherein in accordance with the predetermined program,
the processor updates the model by linearly transforming the estimated value of the beam characteristic.

5. The ion implanter according to claim 1,
wherein in accordance with the predetermined program,
the processor evaluates validity of the model by comparing the plurality of measurement values and the plurality of estimated values of the beam characteristic with each other, and
when the model is evaluated as not valid, the processor updates the model by using the plurality of measurement values and the plurality of estimated values of the beam characteristic.

6. The ion implanter according to claim 5,
wherein in accordance with the predetermined program,
when the model is evaluated as valid, the processor determines the target set for generating the ion beam which satisfies the desired beam characteristic by using the model without updating the model.

7. The ion implanter according to claim 1,
wherein in accordance with the predetermined program,
the processor determines the plurality of sets by using the model.

8. The ion implanter according to claim 7,
wherein in accordance with the predetermined program,
the processor determines the plurality of sets such that an extremum of the estimated value of the beam characteristic estimated from the model is present within a range including the plurality of sets.

9. The ion implanter according to claim 8,
wherein in accordance with the predetermined program,
the processor calculates an extremum of a measurement value of the beam characteristic in a range including the plurality of sets from the plurality of measurement values of the beam characteristic, and
the processor evaluates validity of the model by comparing a first set of setting values of the plurality of operation parameters corresponding to the extremum of the measurement value of the beam characteristic and a second set of setting values of the plurality of operation parameters corresponding to the extremum of the estimated value of the beam characteristic.

10. The ion implanter according to claim 8,
wherein in accordance with the predetermined program,
the processor updates the model such that the extremum of the estimated value of the beam characteristic estimated from the updated model is present in a first set of the setting values of the plurality of operation parameters corresponding to the extremum of the measurement value of the beam characteristic.

11. The ion implanter according to claim 9,
wherein in accordance with the predetermined program,
the processor evaluates the validity of the model by further comparing the extremum of the measurement value of the beam characteristic and the extremum of the estimated value.

12. The ion implanter according to claim 11,
wherein in accordance with the predetermined program,
the processor updates the model such that the extremum of the estimated value of the beam characteristic estimated from the updated model coincides with the extremum of the measurement value of the beam characteristic within the range including the plurality of sets.

13. The ion implanter according to claim 1,
wherein the model includes a first model for estimating a first beam characteristic of the ion beam from the set of the setting values of the plurality of operation parameters and a second model for estimating a second beam characteristic of the ion beam from the set of the setting values of the plurality of operation parameters, and
in accordance with the predetermined program,
the processor updates the first model by using a plurality of first measurement values of the first beam characteristic measured when each of the plurality of sets is set as the plurality of operation parameters and a plurality of first estimated values of the first beam characteristic estimated from each of the plurality of sets by using the first model, and
the processor updates the second model by using a plurality of second measurement values of the second beam characteristic measured when each of the plurality of sets is set as the plurality of operation parameters and a plurality of second estimated values of the second beam characteristic estimated from each of the plurality of sets by using the second model.

14. The ion implanter according to claim 13,
wherein in accordance with the predetermined program,
the processor determines the plurality of sets such that an extremum of an estimated value of the first beam characteristic estimated from the first model is present and an extremum of an estimated value of the second beam characteristic estimated from the second model is present within a range including the plurality of sets.

15. The ion implanter according to claim 1,
wherein the beam generation device includes a lens device that applies at least one of an electric field and a magnetic field to the ion beam to converge or diverge the ion beam, and
the beam characteristic includes at least one of a beam size and a convergence/divergence angle of the ion beam, and
the plurality of operation parameters include two or more operation parameters for controlling an operation of the lens device.

16. An ion implantation method comprising:
measuring a plurality of measurement values of a beam characteristic of an ion beam generated by a beam generation device when each of a plurality of sets of setting values of a plurality of operation parameters is set as a plurality of operation parameters of the beam generation device configured to generate the ion beam by operating in accordance with the plurality of operation parameters;
estimating a plurality of estimated values of the beam characteristic corresponding to each of the plurality of sets by using a model for estimating the beam characteristic from the set of setting values of the plurality of operation parameters;
updating the model by using the plurality of measurement values and the plurality of estimated values of the beam characteristic;
determining a target set of the setting values of the plurality of operation parameters for generating the ion beam which satisfies a desired beam characteristic by using the updated model; and
irradiating a workpiece with the ion beam generated by the beam generation device when the target set is set as the plurality of operation parameters.
